(19) United States
(12) Patent Application Publication
(10) Pub. No.: US 2021/0062332 A1
(43) Pub. Date: Mar. 4, 2021

(54) COMPONENT COATED WITH MULTIPLE TWO-DIMENSIONAL LAYERS, AND COATING METHOD

(71) Applicant: AIXTRON SE, Herzogenrath (DE)

(72) Inventor: Kenneth B.K. TEO, Cambridge (GB)

(21) Appl. No.: 15/733,779

(22) PCT Filed: Apr. 18, 2019
(86) PCT No.: PCT/EP2019/060037

§ 371 Date: Oct. 23, 2020

(30) Foreign Application Priority Data
Apr. 25, 2018 (DE) 10 2018 109 936.3

(51) Int. Cl. C23C 16/26; C01B 32/186; C23C 16/34; C23C 16/56; C23C 28/00

(52) U.S. Cl. CPC C23C 16/26; C01B 32/186; C23C 28/34; C23C 16/56; C23C 16/342

(57) ABSTRACT

A permanently curved component consists of a coated substrate. The substrate is deformable, and the coating consists of multiple layers which are deposited one over another and each of which has layer elements lying adjacent to one another on a plane. The layer elements from adjacent layers are weakly connected together such that the layer elements can move relative to each other upon deforming the coated substrate. In order to produce such a component, the layer elements which lie one over another and which can consist of graphene are first deposited, and then the coated component is deformed such that a closed layer remains.

### RELATED APPLICATIONS

This application is a National Stage under 35 USC 371 of and claims priority to International Application No. PCT/EP2019/060037, filed 18 Apr. 2019, which claims the priority benefit of DE Application No. 10 2018 109 936.3, filed 25 Apr. 2018.

### FIELD OF THE INVENTION

The invention relates to a coated substrate and a method for coating a substrate, wherein a component is produced from the substrate, in which the substrate is curved and the layer is a layer system in which each layer is two-dimensional.

### BACKGROUND

Documents WO 2013/144640 A1, WO 2017/100616 A1 and WO 2015/102746 A2 describe a method for depositing multiple layers which are arranged one over the other, wherein each layer consists of layer elements with a two-dimensional nature that are not connected to each other. A metal foil is used as the substrate.

The deposition of two-dimensional layers on non-deformable substrates is described for example in DE 10 2013 111 791 A1.

Deng et al. “Wrinkled, rippled and crumpled graphene: an overview of formation mechanism, electronic properties, and applications”, Materials Today, Volume 19, Number 4, May 2016, pp. 197-212 describes the deposition of two-dimensional graphene layers on substrates. Document DE 10 2016 118 404 A1 describes a method for manufacturing an electrode for a lithium-ion secondary battery. An apparatus for depositing graphene on thin, rollable substrates is described in DE 10 2015 110 087 A1.

There is a need to produce components, particularly components made from metal, which consist of a deformed substrate, wherein the surface of the component is coated, wherein in particular it is provided that the coating has a plurality of layers deposited one on top of another and each layer is a two-dimensional layer, for which during the deposition of the layer, materials are used which inherently form two-dimensional crystals, such as C, MoS₂, MoTe₂, WTe₂ or other materials of main group IV or comprising a transition metal.

### SUMMARY OF THE INVENTION

The object underlying the invention is that of describing a method with which such a component consisting of a deformed substrate component can be produced.

The object is achieved by the invention specified in the claims, wherein each dependent claim is not only an advantageous development of the independent claims, but also represents an independent solution to the problem.

Firstly and essentially for the purpose of the invention, it is suggested that an initially undeformed substrate, for example a flat or only slightly curved sheet, or a stretched or only slightly bent wire made of metal or another suitable material be coated with a plurality of layers, wherein each layer consists of layer elements which have a two-dimensional character and each can thus be regarded as a monolayer. During the deposition of the layer system, a first layer is first deposited directly onto the surface of the substrate. The first layer consists of a multiplicity of layer elements which lie next to one another in a plane parallel to the surface of the substrate and are preferably not connected to each other. Spacer zones, in which the first layer does not cover the substrate, may be located between the layer elements. The first layer is in particular a fragmented coating of the substrate. According to the invention, at least one second, in particular similar, layer is deposited on this first layer. This layer likewise consists of layer elements which are arranged next to one another in the plane of the second layer and which in particular are not connected to each other. Here too, it is provided in particular that the layer elements are spaced apart from one another by spacer zones. The deposition of the layers generates layer elements which are arranged in a statistically distributed manner in the respective plane. Between the layer elements, which have irregular sizes, there are spacer zones at least in parts thereof, which are of different sizes. The spacer zones of the first layer are thus at least partially covered by layer elements of the second layer, so that the open areas of the surface are reduced. A third layer, which has the same layer properties as the first and second layers, is deposited on the second layer. With the layer elements of the third layer, the remaining open zones of the substrate surface are reduced even further. By depositing further layers onto the previously deposited layer system, the free surface areas are further reduced to zero by covering all the distance zones of the first layer with layer elements of at least one of the further layers. According to the invention, the method is carried out in such a way that the layer elements of a layer are only weakly connected to the layer elements of an adjacent layer, so that the layer elements from adjacent layers can be displaced relative to one another when the substrate is deformed. The deformation may be a bending. The bending of the substrate may have a bending radius that is substantially greater than the layer thickness of a layer. The layer thickness of a layer is less than 2 nm and is preferably in a range between 0.1 and 0.8 nm. The bending radii may be between 0.1 mm and 5 mm. On the outside of the bend, the layer elements are displaced away from each other when bending, so that the distance zones between the layer elements are enlarged. Upon bending in the opposite direction, the layer elements on the inside of the bend are displaced towards one another, so that the distance zones are made smaller. Preferably between 2 and 200 layers are deposited on the substrate. In particular, it is provided that the layers are deposited on the substrate in such a way that when the substrate is deformed the layer elements shift relative to one another, wherein a sufficient number of layers are deposited one above the other so that no open areas of the surface of the substrate are created in the process. The layer elements slide over one another during the deformation without losing their function of covering the distance zones of the first layer. The deformation may be not only a bending but also a stretching or a compression. In the case of a compression, the layer elements are displaced towards each other. During stretching, the layer elements are displaced away from each other. In the first case, the distance zones between the layer elements become smaller. In the second case, the distance zones between the layer elements become larger. The closed coating created during the production of the coating is retained even when the substrate is deformed.

It is envisaged in particular that the substrates are metallic substrates which are coated with graphene. It is further provided in particular that the components are housings or electrodes of batteries or accumulators. With the coating, the electrical conductivity of the substrate may be increased. The chemical resistance may be increased. Even the friction property (tribological property) may be altered. The coating may be conductive or insulating.

The coating may be produced in a gas phase deposition (CVD) process. The catalytic CVD in which in particular the substrate functions as a catalyst is particularly preferred as a production method. An alternative manufacturing method uses a liquid phase coating in which the layer elements are contained as solids in a liquid solution. With this dispersion, the substrate is coated so that the flake-like layer elements can be deposited on the substrate or on a layer that is already deposited. In particular, it is provided that the deposition process generates one monolayer of a layer made from two-dimensional layer elements in each case, wherein the circular equivalent diameter of an irregularly shaped layer element may be in the range between 1 μm and 10 mm. The lateral extension length, that is to say for example, the circle-equivalent diameter of a layer element, is in particular smaller than the bending radius. It is of particular advantage if the shape of the layer elements is retained during the deformation, i.e. in particular the layer elements are not parted during the deformation. The layer elements should preferably only change their position during deformation. The layer elements preferably have circle-equivalent diameters in the range between 1 μm and 100 μm. A preferred deposition method is CVD, in which at least two different process gases are introduced into a process chamber in which the substrate is heated to a process temperature. The process gas may be a carbon-containing gas, for example methane or another hydrocarbon. In addition, an inert gas may be fed into the process chamber. If the coating consists of several components, for example a transition metal and an element from the main group IV, the two components of the layer are fed in gaseous form into the process chamber, each component being fed into the process chamber with its own gas. The layer that forms the layer elements may be a semiconducting layer, a semi-metallic layer, an insulating layer or a sliding layer. It may be applied to a metal sheet which has been precoated. For example, it may be precoated with molybdenum. The deposition of the layer may be carried out in a PVD process (Physical Vapor Deposition), for example by sputtering, vapor deposition or “electroplating”. It may be provided to deposit a three-dimensional layer and then to convert this into a 2D layer by suitable means, for example by first depositing a metal, for example molybdenum, and then by treating the metal layer with a gas, for example with a sulfur-containing gas, for example hydrogen sulfide or di-tert-butyl sulfide. Such a transformation of the metal layer into a two-dimensional MoS₂ layer can take place at 500° C. or at higher temperatures. The temperature range is, for example, from 500 to 1000° C. In a variant thereof, a MoS₂ layer may also be deposited directly as a two-dimensional layer, for example using a metal-organic chemical vapour deposition method (MOCVD). In this process, a molybdenum-containing gaseous starting material is used, for example molybdenum, hexacarbonyl or molybdenum chloride. The second gaseous starting material used is one of the abovementioned sulfur-containing gaseous starting materials, that is to say for example H₂S or di-tert-butyl sulfide. The substrate temperature may be in a range between 500 and 1000° C. here. In a variant of the invention, it is suggested to deposit a layer of BN containing two-dimensional layer elements. Here too, the metal-organic chemical vapour deposition method (MOCVD) can be used. A metal strip is heated to temperatures in a range between 500° C. and 1500° C. A boron-containing gaseous starting material, for example diborane or tri-ethyl borane is used as process gases. Ammonia can be used as nitrogen-containing gaseous starting material. It is also possible to use a gas which contains boron and nitrogen. Borane or borazine is also eligible for consideration. For depositing semi-metallic coatings, such as layers which contain carbon layer elements, a metallic substrate may first be coated with a catalytic substrate. A layer of iron, cobalt, nickel, platinum, copper or another suitable metal may be considered as the catalyst layer. The catalyst layer may be applied by PVD or electroplating. In this case, the substrate is preferably heated to temperatures in the range between 400° C. and 1000° C. This is done in the presence of a carbon-containing gaseous starting material such as methane, ethylene, acetylene or propane. Under these conditions, a two-dimensional carbon/graphene layer is able to be deposited. Alternatively, a substrate may be used which has catalytic properties of its own. This substrate, which is coated while stationary or in a continuous process, can then be heated to temperatures in the range between 400° C. and 1000° C. The deposition of the layer or the layer system is then carried out by introducing a carbon-containing gas into a process chamber of a reactor. For metal substrates which do not have a catalytic surface, higher temperatures are used, for example temperatures in the range between 400° C. and 1500° C.

### BRIEF DESCRIPTION OF THE DRAWINGS

An embodiment of the invention will be explained in the following text with reference to accompanying drawings. These show:

FIG. 1 a schematic cross section through a coated substrate before deformation,

FIG. 2 a representation according to FIG. 1 but after bending, wherein the coating is on the outside of the bend,

FIG. 3 a representation according to FIG. 1 after bending, wherein the coating is on the inside of the bend, and

FIG. 4 a schematic top view of a layer sequence to illustrate the irregular position of the layer elements.

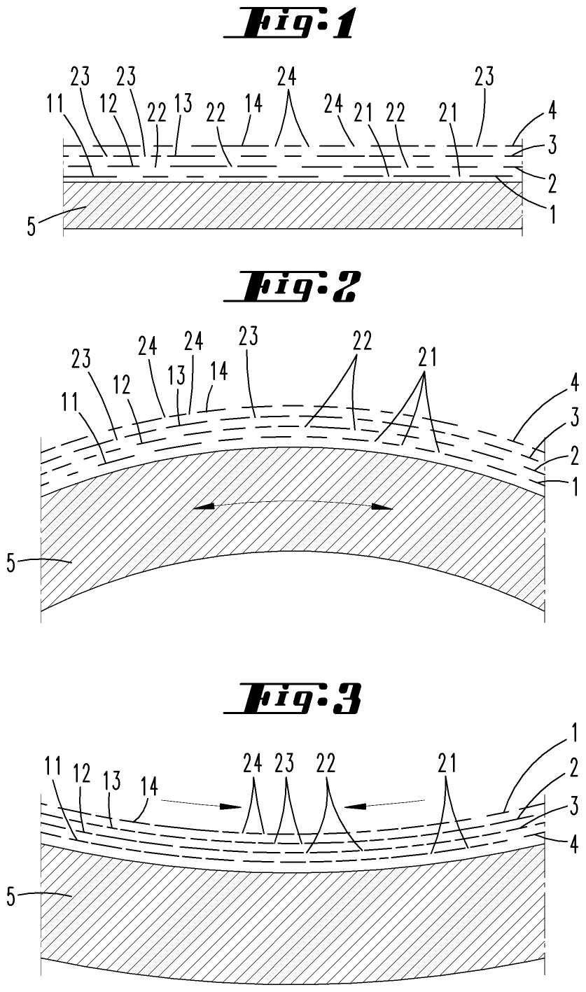

### DETAILED DESCRIPTION

In the figures, the substrate 5 is a metal sheet or a wire and consists of, for example, a metal, in particular Fe, Ni, Co, Cu or an alloy thereof. The substrate 5 is coated with a first graphene layer 1 in a coating plant such as is described in DE 10 2015 110 087 A1, for example. The coating process is performed in such a way that the graphene layer is initially deposited as a monolayer consisting of a multiplicity of irregular layer elements 11. A distance zone 21 remains between each of the layer elements 11, with the result that the substrate 5 is only incompletely coated with the layer elements 11 of the first layer 1.

In a second process step, a second, in particular graphene layer 2 is deposited on the first, in particular graphene layer 1, in particular with the same process parameters. This layer also consists of a multiplicity of layer elements 12 arranged in the layer plane of the second layer 2, between which there are distance zones 22 located. A large proportion of the exposed area of the surface of the substrate 5 formed by the distance zones 21 of the first layer 1 is covered by the layer elements 12 the second layer 2, so that the exposed area of the surface 5 is reduced.

A third, in particular graphene layer 3 consisting of layer elements 13 distributed in the layer plane of the third layer 3, is deposited on the second layer 2, in particular with the same process parameters. The irregular and irregularly distributed layer elements 13 cover not only parts of the distance zones 22 of the second layer but also distance zones 21 of the first layer that are still open and have not been covered by the second layer. With the third layer 3, the exposed area of the surface of the substrate 5 is reduced further.

A fourth layer 4, also consisting of layer elements 14 arranged in the layer plane of the in particular graphene layer 4, between which distance zones 24 remain, is deposited on the third layer 3 in particular with the same process parameters. The statistically distributed layer elements 12, 13, 14 of the second to fourth layers cover the distance zones 21 the layer elements 11 statistically distributed on the substrate surface.

More layers 1, 2, 3, 4 are deposited on the substrate 5 until the surface of the substrate 5 has no more exposed surface areas and the layer sequence 1, 2, 3, 4 is a layer that completely coats the surface.

The layer elements 11, 12, 13, 14 are softly connected to each other. It is substantially Van der Waals forces which hold the layer elements 11, 12, 13, 14 of the various layers 1, 2, 3, 4 together.

The coating is carried out in such a way that the layer elements 11, 12, 13, 14 can be moved relative to each other upon deforming the coated substrate 5, wherein the displacement does not cause the layer elements 11, 12, 13, 14 to lose their function of completely covering the surface 5. The layer elements also do not lose their shape while the layer elements 11, 12, 13, 14 are being displaced. They do not break or tear.

In the embodiment represented in FIG. 2, the coating is disposed on an outer side of the bend. The double arrow symbolises that the layer elements 11, 12, 13, 14 are moved away from each other during bending of the substrate 5. In this context, the distance zones 21, 22, 23, 24 become larger. But the distance zones 21, 22, 23 are sufficiently covered by layer elements 12, 13, 14 so that the coating overall is closed.

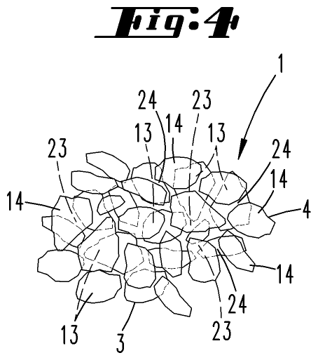

FIG. 3 shows a coating disposed on the inside of a bend. During bending, the layer elements 11, 12, 13, 14 move towards each other in the direction of the arrows shown there. At the same time the distance zones 21, 22, 23, 24 become smaller. But the distance zones 21, 22, 23, 24 are large enough to prevent layer elements from colliding and thereby destroying the layer system.

In variants that are not shown, it is provided that coated substrate 5 is either stretched or compressed. When stretched, the distance zones 21, 22, 23, 24 become larger, as is shown in FIG. 2. In the case of a compression, the distance zones 21, 22, 23, 24 become smaller, as is shown in FIG. 3.

During the deformation, the material thickness of the substrate 5 may also be reduced. As a consequence of this, the distances between the layer elements 11, 12, 13, 14 increase.

Regardless of the type of deformation, it may be provided that the layer elements 11, 12, 13, 14 keep their shape during deformation and only slide relative to the respective adjacent layer as they are moved. The layer elements 11, 12, 13, 14 each consist of a two-dimensional monolayer. The layer thickness may be in the range from 0.3 nm to 0.65 nm.

In the embodiment, the layer elements 11, 12, 13, 14 lie parallel to each other, each being arranged in a plane associated with the respective layer. But it is also possible that the layer elements 11, 12, 13, 14 partially overlap to form a scaly structure. In particular, it is also provided that the layer elements 11, 12, 13, 14 lie one over the other in a zigzag pattern.

A further exemplary embodiment relates to the deposition of a two-dimensional MoS₂ layer or layer sequence on a substrate, wherein each layer includes the layer elements described above. A molybdenum layer is applied to a metal substrate such as a metal sheet. This may be done by sputtering, vapor deposition or electroplating. The sputtering can be done at a power of 300 W at radio frequency, wherein argon is used as the carrier gas with a flow of 10 sccm. The process takes place at a total pressure of 10⁻³ mbar for about 5 min. In this deposition process, an approximately 5 nm thick layer of molybdenum is deposited on the substrate. The metal substrate is then heated to a temperature up to 700° C. This takes place in a hydrogen atmosphere at a pressure of 10 mbar. The hydrogen flow can be at 250 sccm. At a target temperature of 700° C., the metal substrate with the deposited thin layer of molybdenum is exposed to a process gas containing sulfur. This sulfur-containing process gas can be fed together with an inert gas, for example argon or hydrogen, into a process chamber of a reactor. The sulfur-containing process gas can be produced by heating sulfur powder in a crucible to about 500° C. The sulfur vapour reacts with the molybdenum of the molybdenum layer, so that one or more layers form one above the other. Two-dimensional MoS₂ layer elements form in superposed planes. The treatment of the molybdenum layer with a gaseous, sulfur-containing starting material takes place for about 5 min.

Alternatively, a metal sheet may be heated to a temperature of 850° C. in a nitrogen atmosphere and/or hydrogen atmosphere. It is envisaged that the metal sheet is treated in an atmosphere of 250 sccm nitrogen and 1000 sccm hydrogen at 100 mbar at 850° C. Under these conditions the metal substrate is exposed to a mixture of 0.1 nM/min molybdenum hexacarbonyl and 10 nM/min di-tert-butyl sulfide. These starting materials are added to the original gas mixture. The treatment process at 100 mbar is carried out for about one hour. During this treatment time, two-dimensional molybdenum disulfide layer elements form.

In a further embodiment, an insulating two-dimensional coating containing BN (boron nitride) is formed. The boron nitride layer or the layer sequence containing boron nitride layer elements is produced in the MOCVD process. The metallic substrate is heated to temperatures from 500° C. to 1500° C. and is charged with a boron-containing, in particular gaseous starting material. Diborane or triethylborane may be considered. As the second gaseous starting material, a nitrogen-containing starting material is used. Ammonia is possible. It may further be provided that a starting material containing both boron and nitrogen is used, for example ammonium borane or ammonium borazine. It may be provided in particular that the substrate has been previously coated with a catalytic metal, for example nickel or copper. It is also possible to use a nickel or copper substrate which itself exhibits a catalytic effect.

In this context, the metal is heated to temperatures of about 1000° C. in a hydrogen atmosphere (200 sccm). This is done under a total pressure of 1 mbar. The metal substrate is then treated in a flow of 1 sccm borazine or ammonium diborane. Borazine or ammonium diborane are evaporated from a liquid phase. This can take place a temperature of 250° C. The gas containing boron and nitrogen is added to the inert gas, which is in particular hydrogen. In this treatment, two-dimensional boron nitride layer elements form, which are arranged in the manner described above, giving rise to a layer sequence.

For depositing a semi-metallic or semiconductive coating, a two-dimensional, carbon-containing layer is deposited. Such a layer is usually a graphene layer. Two variants of the method are also suggested for depositing a graphene layer. A catalytically active substrate, for example of iron, cobalt, nickel, platinum or copper may be used as substrate. Alternatively, a different substrate is used which is first coated with a catalytic metal such as iron, cobalt, nickel, platinum or copper. This may be done by a PVD, for example by electroplating. In such case, the substrate is heated to temperatures in the range between 400° C. and 1000° C. In the presence of a carbon-containing gas, for example, methane, ethylene, acetylene or propane, a two-dimensional graphene layer is formed on the surface that is prepared in this way. The already catalytically active substrate may also be used with the same method. If the substrate is not catalytic, the coating process is preferably carried out in a temperature range between 400 and 1500° C.

In order to furnish a non-catalytic substrate with a catalytic surface, the catalytically active metal, for example iron, cobalt, nickel, platinum or copper may be sputtered onto the surface. This is done for example in a plasma or with an electron beam at a power of 300 W and radio frequency. The carrier gas used is argon with a flow of 10 sccm. The pressure here is in the range between 10⁻³ mbar. The deposition process takes 10 min. During this time, an approximately 10 nm thick layer of cobalt or nickel is deposited on the metal. Electroplating is suggested as an alternative method of deposition. However, it is also envisaged to apply a catalytically active layer to the substrate galvanically. In this case, the substrate is placed in an electrolytic bath. A negative voltage is applied to the substrate. After the application of the catalyst, the metal substrate is heated to temperatures up to 800° C., this taking place in a gas environment consisting of hydrogen and argon. This is preferably done under a total pressure of 25 mbar. A flow of 1000 sccm hydrogen and 250 sccm argon is fed into the process chamber of a reactor used for this purpose. By feeding a carbon-containing gas, for example, acetylene (10 sccm for 5 min), a graphene layer is deposited. The carbon-containing gas is fed into the process chamber in addition to the inert gas, with the result that the two-dimensional carbon layer system is deposited on the catalytic metal layer.

Under the similar process parameters, but at temperatures of up to 1000° C., a metal substrate may be coated which has inherently catalytic function, that is to say it consists in particular of iron, cobalt, nickel, platinum or copper.

In alternative methods, the metal substrate, which is either inherently catalytic or coated with a catalytic coating, may be heated up to only 700° C. for the purpose of depositing the two-dimensional carbon layers, wherein this is done in the presence of nitrogen (950 sccm) and hydrogen (40 sccm). 10 sccm acetylene is then fed into the process chamber for 5 min in addition to this carrier gas mixture to deposit the two-dimensional graphene layer system.

Different flow values of the process gases may also be used depending on the size of the process chamber and the size of the substrates to be coated. Likewise, the temperatures may be adapted to the respective conditions and in particular the starting materials used.

The substrate is either stationary in a process chamber or passes through the process chamber as an endless strip “roll to roll”. Uncoated substrate material enters the process chamber on one side, is coated therein with a layer system, wherein the layers are deposited one on top of the other sequentially and each contain layer elements. On the other side of the process chamber, the coated substrate emerges from the process chamber again.

The above notes serve to explain the inventions described in the application as a whole, which further develop the prior art at least through the following combinations of features, and also individually in each case, wherein two, several or all of these combinations of features may also be combined, namely:

Permanently curved component consisting of a coated substrate 5, wherein the substrate 5 is deformable and the coating consists of multiple layers 1, 2, 3, 4 which are deposited one over the other and each of which has layer elements 11, 12, 13, 14 lying adjacent to one another in one plane, wherein the layer elements 11, 12, 13, 14 of layers 1, 2, 3, 4 lying one over the other are weakly connected together such that they can be moved relative to each other upon deforming of the coated substrate 5.

Method for producing deformed, coated components with the steps:
Depositing multiple layers 1, 2, 3, 4 which are arranged one over the other and each having layer elements 11, 12, 13, 14 lying adjacent to one another in one plane on a deformable substrate 5, wherein the layer elements 11, 12, 13, 14 of the layers 1, 2, 3, 4 lying one over the other are weakly connected together such that they can be moved relative to each other upon deforming of the substrate 5;
Deforming the coated substrate 5 to produce a permanently deformed component.

A component or a method which are characterized in that the substrate 5 is a thin metal sheet or a wire and/or that the substrate 5 consists of Fe, Ni, Co, Cu or an alloy with at least one of the aforementioned elements and/or is a coated metal.

A component or a method which are characterized in that the layers 1, 2, 3, 4 and/or the layer elements 11, 12, 13, 14 consist of two-dimensional crystals.

A component or a method which are characterized in that the lateral surface extension of the layer elements 11, 12, 13, 14 is much larger than the layer thickness thereof, and in particular at least one thousand times as large.

A component or a method which are characterized in that the layer elements 11, 12, 13, 14 of layers 1, 2, 3, 4 that are different from each other are slidably superposed on each other and/or overlap such that even after bending, the surface of the substrate 5 is completely coated with layer elements 11, 12, 13, 14.

A component or a method which are characterized in that distance zones 21, 22, 23, 24 are arranged between layer elements 11, 12, 13, 14 of a respective layer 1, 2, 3, 4, wherein the distance zones 21 of a first layer 1 deposited directly on the substrate 5 are covered by each of at least one layer element 12, 13, 14 of a further layer 2, 3, 4 deposited on the first layer 1.

A component or a method which are characterized in that the material of the layers 1, 2, 3, 4 is graphene or another group-IV element, a compound MX₂, wherein M is a transition metal and X is a group-VI element, for example MoS₂, MoTe₂, WTe₂ or BN.

A component or a method which are characterized in that the layer thickness of the layers 1, 2, 3, 4 is less than 2 nm and in particular is in the range between 0.1 and 0.8 nm, and/or that the circle-equivalent diameter of a layer element 11, 12, 13, 14 is in the range between 1 μm and 10 mm, in particular in a range between 1 μm and 100 μm or in a range between 100 μm and 10 mm, and/or that the substrate 5 is coated with 2 to 200 layers 1, 2, 3, 4.

A component or a method which are characterized in that a chemical gas phase coating CVD, in particular a catalytic CVD during which in particular the substrate 5 exhibits a catalytic effect or a liquid phase coating in which the layer elements 11, 12, 13, 14 are deposited in particular in the form of a dispersion, is used for depositing the layers, and/or that two different process gases are used in a vapor deposition and/or heat is supplied to the substrate.

A component or a method which are characterized in that the deformation is a three-dimensional deformation, in particular a bending, and/or that the deformation is a stretching or a compression.

A component or a method which are characterized in that the coating increases the electrical conductivity and/or increases the chemical resistance and/or changes the tribological property of the surface, and/or that the coating is electrically conductive or electrically insulating, and/or that the bending radius of bending lines of the substrate 5 lies in the range between 0.1 to 5 mm.

A component or a method which are characterized in that the component is a housing or an electrode of a battery or a rechargeable battery.

A method which is characterized in that the substrate coated in this way is deformed to produce a permanently deformed component, wherein the number of layers 1, 2, 3, 4 is selected such that after the deformation, during which the layer elements 11, 12, 13, 14 are moved relative to each other, no open areas of substrate 5 are left, wherein the bending radii are between 0.1 mm and 5 mm.

All disclosed features are essential to the invention (individually, but also in combination with each other). The disclosure of the associated/attached priority documents (copy of the prior application) is hereby also incorporated in full in the disclosure of the application, also for the purpose of including features of these documents in claims of the present application. Even without the features of a referenced claim, by their features the subclaims characterize independent inventive developments of the prior art, in particular in order to carry out divisional applications based on these claims. The invention specified in each claim may additionally comprise one or more of the features described in the preceding description, in particular with reference numbers and/or given in the reference number list. The invention also relates to design forms in which individual features of those mentioned in the above description are not realized, in particular insofar as they are recognizably dispensable for the respective purpose or can be replaced by other technically equivalent means.

### LIST OF REFERENCE NUMBERS

1 Layer
2 Layer
3 Layer
4 Layer
5 Substrate
11 Layer element
12 Layer element
13 Layer element
14 Layer element
21 Distance zone
22 Distance zone
23 Distance zone
24 Distance zone

What is claimed is:

1. A permanently curved component comprising:
a substrate (5) that is coated with a coating and is deformable; and
the coating, wherein the coating comprises multiple layers (1, 2, 3, 4) which are deposited one over another, wherein each of the layers includes layer elements (11, 12, 13, 14) that lie adjacent to one another in a plane, wherein the layer elements (11, 12, 13, 14) from adjacent ones of the layers (1, 2, 3, 4) weakly connected together such that the layer elements (11, 12, 13, 14) from the adjacent layers are able to move relative to each other when the coated substrate (5) is deformed.

2. A method for producing deformed, coated components, the method comprising:
depositing a coating on a substrate (5), wherein the coating comprises multiple layers (1, 2, 3, 4) which are arranged one over another and each has layer elements (11, 12, 13, 14) that lie adjacent to one another in a plane, and wherein the layer elements (11, 12, 13, 14) from adjacent ones of the layers (1, 2, 3, 4) are weakly connected together such that the layer elements (11, 12, 13, 14) from the adjacent layers are able to move relative to each other when the substrate (5) is deformed; and
deforming the coated substrate (5) to produce a permanently deformed component.

3. The permanently curved component of claim 1, wherein at least one of:
the substrate (5) is a thin metal sheet or a wire,
the substrate (5) consists of Fe, Ni, Co or Cu,
the substrate (5) consists of an alloy with at least Fe, Ni, Co or Cu, or
the substrate (5) is a coated metal.

4. The permanently curved component of claim 1, wherein the layers (1, 2, 3, 4) and/or the layer elements (11, 12, 13, 14) consist of two-dimensional crystals.

5. The permanently curved component of claim 1, wherein a lateral surface extension of each of the layer elements (11, 12, 13, 14) is larger than a layer thickness thereof.

6. The permanently curved component of claim 1, wherein the layer elements (11, 12, 13, 14) of ones of the layers (1, 2, 3, 4) that are different from each other are slidably superposed on each other and/or overlap such that even after bending, a surface of the substrate (5) is completely coated with the layer elements (11, 12, 13, 14).

7. The permanently curved component of claim 1, further comprising distance zones (21, 22, 23, 24) arranged between the layer elements (11, 12, 13, 14) of a respective one of the layers (1, 2, 3, 4), wherein the distance zones (21) of a first one of the layers (1) deposited directly on the substrate (5) are covered by each of at least one layer element (12, 13, 14) of one of the layers (4) deposited over the first layer (1).

8. The permanently curved component of claim 1, wherein the layers (1, 2, 3, 4) are composed of graphene, a group IV element, BN, or a compound with chemical composition MX₂ wherein M is a transition metal and X is a group-VI element.

9. The permanently curved component of claim 1, wherein at least one of:
a layer thickness of each of the layers (1, 2, 3, 4) is less than 2 nm,
a circle-equivalent diameter of each of the layer elements (11, 12, 13, 14) is between 1 μm and 10 mm, or
a total number of the layers is between 2 to 200 inclusive.

10. The method of claim 2, wherein at least one of:
a chemical gas phase coating chemical vapor deposition (CVD) is used for depositing the layers,
two different process gases are used in a vapor deposition, or
heat is supplied to the substrate (5).

11. The permanently curved component of claim 1, wherein the deformation is at least one of a three-dimensional deformation, a bending, a stretching or a compression.

12. The permanently curved component of claim 1, wherein at least one of:
the coating increases an electrical conductivity of the substrate (5),
the coating increases a chemical resistance of the substrate (5),
the coating changes a tribological property of a surface of the substrate (5),
the coating is electrically conductive or electrically insulating, or
a bending radius of bending lines of the coated substrate (5) lies in a range between 0.1 to 5 mm.

13. The permanently curved component of claim 1, wherein the permanently curved component is at least one of:
a housing,
an electrode of a battery, or
an electrode of a rechargeable battery.

14. A method for producing a coated component, the method comprising:
depositing a coating on a deformable substrate (5), wherein the coating comprises multiple layers (1, 2, 3, 4) arranged one over another, each of the layers having multiple unconnected layer elements (11, 12, 13, 14) that lie adjacent to each other in a plane and have a two-dimensional character, and wherein the layer elements (11, 12, 13, 14) of adjacent ones of the layers are connected to each other via Van der Waals forces; and
deforming the coated substrate (5) to produce a permanently deformed component, wherein a total number of the layers (1, 2, 3, 4) is selected such that after the deformation, during which the layer elements (11, 12, 13, 14) move relative to each other, no open areas of the substrate (5) are left, wherein deforming the coated substrate (5) comprises bending the coated substrate (5) with a bending radii between 0.1 mm and 5 mm.

15. (canceled)

16. The method of claim 2, wherein the layers (1, 2, 3, 4) and/or the layer elements (11, 12, 13, 14) consist of two-dimensional crystals.

17. The method of claim 2, wherein a lateral surface extension of each of the layer elements (11, 12, 13, 14) is larger than a layer thickness thereof.

18. The method of claim 2, wherein the layers (1, 2, 3, 4) are composed of graphene, a group-IV element, BN, or a compound with chemical composition MX₂, wherein M is a transition metal and X is a group-VI element.

19. The method of claim 2, wherein at least one of:
a layer thickness of each of the layers (1, 2, 3, 4) is less than 2 nm,
a circle-equivalent diameter of each of the layer elements (11, 12, 13, 14) is between 1 μm and 10 mm, or
a total number of the layers is between 2 to 200 inclusive.

20. The method of claim 2, wherein the deformation is at least one of a three-dimensional deformation, a bending, a stretching or a compression.

21. The method of claim 2, wherein at least one of:
the coating increases an electrical conductivity of the substrate (5),
the coating increases a chemical resistance of the substrate (5),
the coating changes a tribological property of a surface of the substrate (5),
the coating is electrically conductive or electrically insulating, or
a bending radius of bending lines of the coated substrate (5) lies in a range between 0.1 to 5 mm.
